(19) United States
(12) Patent Application Publication
(10) Pub. No.: US 2024/0196586 A1
(43) Pub. Date: Jun. 13, 2024

(54) STACKED AND NON-STACKED TRANSISTORS WITH DOUBLE-SIDED INTERCONNECTS

(71) Applicant: International Business Machines Corporation, Armonk, NY (US)

(72) Inventors: Brent A. Anderson, Jericho, VT (US); Albert M. Chu, Nashua, NH (US); Carl Radens, LaGrangeville, NY (US); Ruilong Xie, Niskayuna, NY (US)

(21) Appl. No.: 18/063,956

(22) Filed: Dec. 9, 2022

(51) Int. Cl. H10B 10/00

(52) U.S. Cl. CPC H01L 27/1108; H01L 27/1116

(57) ABSTRACT

A semiconductor structure is provided that includes a stacked transistor including at least one transistor stacked over another transistor and a non-stacked transistor integrated on a same wafer. Both the stacked transistor and the non-stacked transistor include frontside and backside interconnects.

### BACKGROUND

The present application relates to semiconductor technology, and more particularly to a semiconductor structure including a stacked transistor including at least one transistor stacked over another transistor and located laterally adjacent to a non-stacked transistor, wherein both the stacked transistor and the non-stacked transistor include frontside and backside interconnects.

A stacked transistor includes at least a first transistor stacked vertically over a second transistor. Stacking can permit smaller scaled devices and increase the density of the devices. Integrating a stacked transistor and a non-stacked transistor on a same wafer is attractive since the non-stacked transistor can provide a high performance, low density device (e.g., a logic device), while the stacked transistor can provide a low performance, high density device (e.g., a static random access memory (SRAM) device). The stacked transistor greatly reduces the area and no design change is needed to the non-stacked transistor.

### SUMMARY

A semiconductor structure is provided that includes a stacked transistor including at least one transistor stacked over another transistor and a non-stacked transistor integrated on a same wafer. Both the stacked transistor and the non-stacked transistor include frontside and backside interconnects, which further enhances the attractiveness of such an integrated device.

In one aspect of the present application, a semiconductor structure is provided. In one embodiment of the present application, the semiconductor structure includes a non-stacked transistor having a frontside and a backside, and a stacked transistor located laterally adjacent to the non-stacked transistor and having a frontside and a backside, the stacked transistor including two or more transistors stacked one atop the other. The semiconductor structure further includes a frontside interconnect located on the frontside of both the non-stacked transistor and the stacked transistor, and a backside interconnect located on the backside of both the non-stacked transistor and the stacked transistor. The structure of the present application combines a high performance, low density device (e.g., logic device), with a low performance, high density device (e.g., a SRAM device), while providing both frontside and backside wiring. In the present application, the term “frontside” denotes an area of a wafer in which transistors (and other semiconductor devices) are formed, while the term “backside” denotes an area of a wafer opposite the area including the transistors.

In embodiments of the present application, the frontside interconnect includes a multilayered frontside interlayer dielectric (ILD) material structure having frontside contact structures embedded therein, and a frontside back-end-of-the-line (BEOL) structure located on the multilayered frontside ILD material structure. The frontside contact structures enable electrically connection between the stacked transistor and the non-stacked transistor with the frontside BEOL structure, and the frontside BEOL structure permits electrically connection to the other devices.

In embodiments of the present application, the semiconductor structure can further include a carrier wafer located on the frontside BEOL structure.

In embodiments of the present application, the frontside contact structures include a first frontside gate contact structure electrically connecting a gate structure of the non-stacked transistor to the frontside BEOL structure, a second gate contact structure electrically connecting a gate structure of each of the transistors of the stacked transistor to the frontside BEOL structure, a first frontside source/drain contact structure electrically connecting a first source/drain region of the non-stacked transistor to the frontside BEOL structure, and a second frontside source/drain contact structure electrically connecting a first source/drain region and a second source/drain region of a first transistor of the two or more transistors of the stacked transistor to the frontside BEOL structure.

In embodiments of the present application, the backside interconnect includes a first backside metal level including a plurality of first backside electrically conductive structures, and a second backside metal level located on the first backside metal level and including a plurality of second backside electrically conductive structures. The backside interconnect can provide power to the stacked transistor and the non-stacked transistor without taking up any area on the frontside of the wafer for the same purpose (i.e., power delivery)

In embodiments of the present application, one of the first backside electrically conductive structures of the plurality of first backside electrically conductive structures is electrically connected to a second source/drain region of the non-stacked transistor by a first backside source/drain contact structure, and at least two other first backside electrically conductive structures of the plurality of first backside electrically conductive structures are electrically connected to a first source/drain region and a second source/drain region of a second transistor of the two or more transistors of the stacked transistor by second backside source/drain contact structures.

In embodiments of the present application, one of the second backside electrically conductive structures is electrically connected to the first backside electrically conductive structure that is electrically connected to the second source/drain region of the non-stacked transistor by a first backside metal via.

In embodiments of the present application, another of the second backside electrically conductive structures is electrically connected to the first backside electrically conductive structures that is electrically connected to the second source/drain region of one of the transistors of the stacked transistor by a second backside metal via.

In embodiments of the present application, the non-stacked transistor is a nanosheet transistor. Nanosheet transistors are attractive since they provide smaller scaled devices, with high density.

In embodiments of the present application, the two or more transistors of the stacked transistor are nanosheet transistors.

In embodiments of the present application, the structure can further include a dielectric structure separating each nanosheet transistor. The dielectric structure isolates the stacked transistors from each other.

In embodiments of the present application, the dielectric structure is continuous and includes a dielectric gate cut pillar, a middle dielectric isolation layer, a dielectric spacer, and a bottom dielectric isolation layer, wherein a first end of the middle dielectric isolation layer is connected to the dielectric gate cut pillar, and a second end of the middle dielectric isolation layer is connected to the bottom dielectric isolation layer, and the dielectric gate cut pillar contacts the frontside interconnect and the bottom dielectric isolation layer contacts the backside interconnect.

In embodiments of the present application, the middle dielectric isolation layer and the bottom dielectric isolation layer are orientated parallel to each semiconductor material nanosheet of each nanosheet transistor of the two or more transistors of the stacked transistor, and the dielectric gate cut pillar, and the dielectric gate cut pillar and the dielectric spacer are orientated perpendicular to each semiconductor material nanosheet of each nanosheet transistor of the two or more transistors of the stacked transistor.

In embodiments of the present application, each of the two or more transistors of the stacked transistor is of a same conductivity type.

In embodiments of the present application, the two or more transistors of the stacked transistor include a top transistor having a first conductivity type and a bottom transistor having a second conductivity type that is different from the first conductivity type.

In embodiments of the present application, the first conductivity type is n-type, and the second conductivity type is p-type.

In embodiments of the present application, the first conductivity type is p-type, and the second conductivity type is n-type.

In embodiments of the present application, the non-stacked transistor and the stacked transistor have a same device height, and the non-stacked transistor has an upper surface and a lower surface, wherein the upper surface of the non-stacked transistor is coplanar with an upper surface of the stacked transistor, and the lower surface of the non-stacked transistor is coplanar with a lower surface of the stacked transistor. This aspect of the present application signifies that the stacked transistor and the non-stacked transistor are at a same device level and thus allowing for easy frontside and backside interconnects to be formed.

In embodiments of the present application, the non-stacked transistor includes a vertically stacked semiconductor nanosheets, and each of the transistors of the stacked transistor includes a vertically stacked semiconductor nanosheets, wherein a total number of vertically stacked semiconductor nanosheets of the non-stacked transistor is equal to, or greater than, a total number of vertically stacked semiconductor nanosheets of the two or more transistors of the stacked transistor.

In embodiments of the present application, the non-stacked transistor is a logic device, and the two or more transistors of the stacked transistor are SRAM devices.

### BRIEF DESCRIPTION OF THE DRAWINGS

FIG. 1 is a top down view illustrating a device layout including a non-stacked transistor device region and a laterally adjacent stacked transistor device region that will be used in the present application, wherein each device region includes a plurality of gate structures that are oriented parallel to each other and perpendicular to an active area.

FIGS. 2A-2B are cross sectional views through Y1-Y1, and Y2-Y2, respectively, shown in FIG. 1 of an exemplary structure that can be used in the present application, the exemplary structure including a sacrificial placeholder material layer located on a substrate, and a first material stack of alternating first sacrificial semiconductor material layers and first semiconductor channel material layers.

FIGS. 3A-3B are cross sectional views of the exemplary structure shown in FIGS. 2A-2B, respectively, after forming a hard mask over the first material stack in the non-stacked transistor device region, and recessing the first material stack in the stacked transistor device region to provide a reduced height first material stack in the stacked transistor device region.

FIGS. 4A-4B are cross sectional views of the exemplary structure shown in FIGS. 3A-3B, respectively, after forming a first sacrificial semiconductor material layer and another sacrificial placeholder material layer on the reduced height first material stack in the stacked transistor device region, and forming a second material stack of alternating second sacrificial semiconductor material layers and second semiconductor channel material layers.

FIGS. 5A-5B are cross sectional views of the exemplary structure shown in FIGS. 4A-4B, respectively, after removing the hard mask over the first material stack in the non-stacked transistor device region, patterning the first material stack and the sacrificial placeholder material layer in the non-stacked transistor device region to provide a first patterned material stack, patterning the second material stack, the another sacrificial placeholder material layer, the first sacrificial semiconductor material layer and the reduced height first material stack in the stacked transistor device region to provide a second patterned material stack, and forming a shallow trench isolation structure in the substrate and at the footprint of both the first and second patterned material stacks.

FIGS. 6A-6E are cross sectional views of the exemplary structure shown in FIGS. 5A-5B after forming a sacrificial spacer on one side of the second patterned material stack, and forming a sacrificial gate material layer, and a sacrificial hard mask layer in both the non-stacked transistor device region and the stacked transistor device region; note FIG. 6A is through cut Y1-Y1 shown in FIG. 1, FIG. 6B is through cut X1-X1 shown in FIG. 1, FIG. 6C is through cut Y2-Y2 shown in FIG. 1, FIG. 6D is through cut Y2′-Y2′ shown in FIG. 1, and FIG. 6E is through cut X2-X2 shown in FIG. 1.

FIGS. 7A-7E are cross sectional views of the exemplary structure shown in FIGS. 6A-6E, respectively, after patterning the sacrificial hard mask layer and the sacrificial gate material layer to provide hard mask capped sacrificial gate structures in both the non-stacked transistor device region and the stacked transistor device region.

FIGS. 8A-8E are cross sectional views of the exemplary structure shown in FIGS. 7A-7E, respectively, after removing the remaining sacrificial placeholder material layer from the first patterned material stack, and the sacrificial spacer and the remaining sacrificial placeholder material layers from the second patterned material stack.

FIGS. 9A-9E are cross sectional views of the exemplary structure shown in FIGS. 8A-8E, respectively, after nanosheet device processing that can include forming, at a same time, a gate dielectric spacer along sidewalls of the hard mask capped sacrificial gate structures in both the non-stacked transistor device region and the stacked device region, a bottom dielectric isolation layer in a first gap previously occupied by the sacrificial placeholder material layer in the non-stacked transistor device region, another bottom dielectric isolation layer in a first gap previously occupied by the sacrificial placeholder material layer in the stacked transistor device region, a middle dielectric isolation layer in a second gap previously occupied by the another sacrificial placeholder material layer in the stacked transistor device region, and a stacked device gate spacer in a third gap previously occupied by the sacrificial spacer, converting the first patterned material stack into a first nanosheet containing stack, and the second patterned material stack into a second nanosheet containing stack, recessing each sacrificial semiconductor material nanosheet present in the first and second nanosheet containing stacks, forming an inner spacer laterally adjacent to each recessed semiconductor material nanosheet, and forming source/drain regions and first frontside ILD material layers in each of the device regions.

FIGS. 10A-10E are cross sectional views of the exemplary structure shown in FIGS. 9A-9E, respectively, after gate processing which includes removing the sacrificial gate structure to reveal the nanosheet containing material stacks in the respective device region, removing the recessed sacrificial semiconductor material nanosheets from the revealed nanosheet containing stack, forming a gate structure, and forming a dielectric gate cut pillar cutting the gate structure in the stacked transistor device region.

FIGS. 11A-11E are cross sectional views of the exemplary structure shown in FIGS. 10A-10E, respectively, after forming a frontside interconnect including frontside contact structures, a frontside BEOL structure and a carrier wafer.

FIGS. 12A-12E are cross sectional views of the exemplary structure shown in FIGS. 11A-11E, respectively, after flipping the wafer 180° to physically expose a backside of the substrate; in these drawings the substrate includes a first semiconductor material layer, an etch stop layer, and a second semiconductor material layer.

FIGS. 13A-13E are cross sectional views of the exemplary structure shown in FIGS. 12A-12E, respectively, after removing the physically exposed first semiconductor material layer of the substrate to physically expose the etch stop layer of the substrate.

FIGS. 14A-14E are cross sectional views of the exemplary structure shown in FIGS. 13A-13E, respectively, after removing the physically exposed etch stop layer of the substrate to physically expose the second semiconductor material layer of the substrate.

FIGS. 15A-15E are cross sectional views of the exemplary structure shown in FIGS. 14A-14E, respectively, after removing the physically exposed second semiconductor material layer of the substrate.

FIGS. 16A-16E are cross sectional views of the exemplary structure shown in FIGS. 15A-15E, respectively, after forming a backside interconnect including a first backside metal level including a plurality of first backside electrically conductive structures, and a second backside metal level located on the first backside metal level and including a plurality of second backside electrically conductive structures.

FIG. 17 illustrates a semiconductor structure in accordance with the present application including a non-stacked transistor device region including a full height nanosheet logic nFET and a full height nanosheet logic pFET, and a stacked transistor device region including reduced height stacked nanosheet SRAM FETs.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Referring first to FIG. 1, there is illustrated a device layout including a non-stacked transistor device region 100 and a laterally adjacent stacked transistor device region 102 that will be used in the present application. Each device region includes a plurality of gate structures, GS, which are oriented parallel to each other and perpendicular to an active area, AA. The non-stacked transistor device region 100 includes a cut X1-X1 which is in a lengthwise direction of the active area, AA, and through the active area, AA, and a Y1-Y1 which is in a lengthwise direction of the gate structures and through one of the gate structures, GS. The stacked transistor device region 102 includes a cut X2-X2 which is in a lengthwise direction of the active area, AA, and through the active area, AA, a Y2-Y2 which is in a lengthwise direction of the gate structures and through one of the gate structures, GS, and a cut Y2′-Y1 which located between two adjacent gate structures, GS, and in a source/drain region.

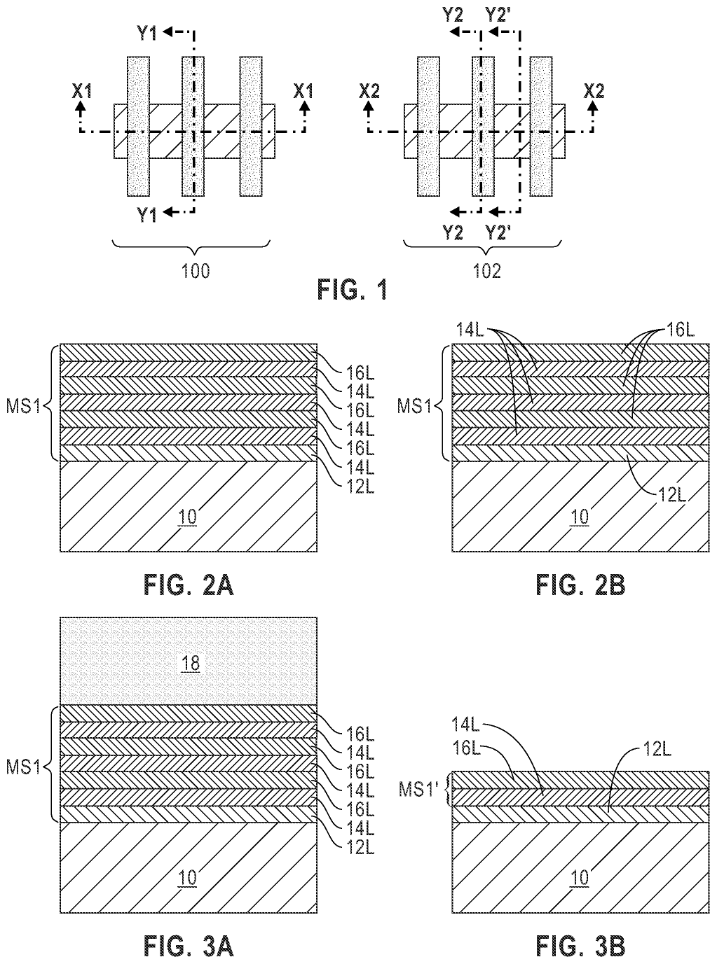

Referring now to FIGS. 2A-2B, there are illustrated an exemplary structure that can be used in the present application; FIG. 2A is in the non-stacked device region 100 and through the Y1-Y1 cut shown in FIG. 1, while FIG. 2B is in the stacked device region 102 and through the Y2-Y2 cut shown in FIG. 1. It is noted that the structure shown in FIGS. 2A and 2B is a single piece structure and it is located on a same substrate (or wafer). Notably, the illustrated exemplary structure shown in FIGS. 2A and 2B includes a sacrificial placeholder material layer 12L located on a substrate 10, and a first material stack MS1 of alternating first sacrificial semiconductor material layers 14L and first semiconductor channel material layers 16L.

The substrate 10 can include a semiconductor substrate that includes at least one semiconductor material having semiconducting properties. Examples of semiconductor materials that can be used in the present application in providing substrate 10 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments of the present application, the substrate 10 can be a bulk semiconductor substrate, i.e., a substrate that is composed entirely of at least one semiconductor material. In other embodiments of the present application, the substrate 10 can be a semiconductor-on-insulator substrate (SOI), i.e., a substrate that includes a bottom semiconductor material layer, a buried insulator layer and a top semiconductor material layer.

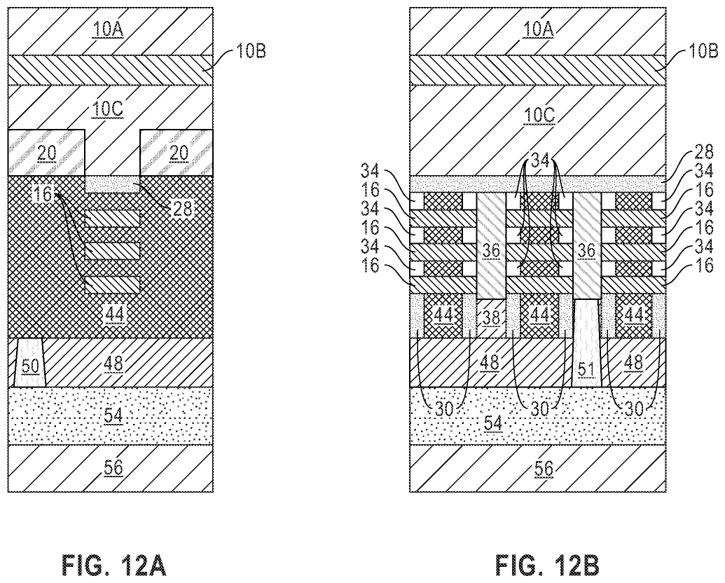

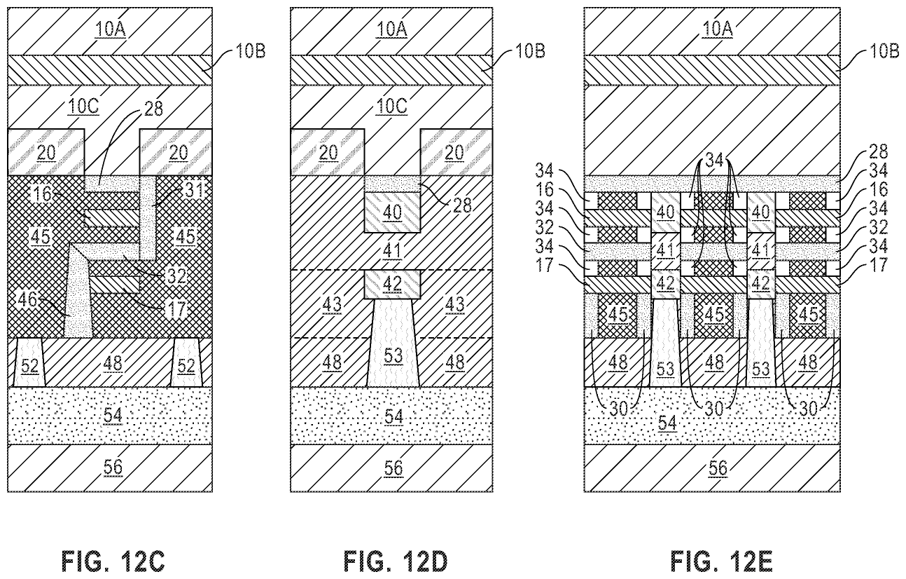

In some embodiments, and as will be subsequently illustrated in FIGS. 12A-12E, the substrate 10 can include a first semiconductor material layer 10A, an etch stop layer 10B and a second semiconductor material layer 10C. The first semiconductor material layer 10A of the substrate 10 is composed of a first semiconductor material. The second semiconductor material layer 10C of the substrate 10 is composed of a second semiconductor material. The second semiconductor material that provides the second semiconductor material layer 10C can be compositionally the same as, or compositionally different from, the first semiconductor material that provides the first semiconductor material layer 10A. In some embodiments of the present application, the etch stop layer 10B of the substrate 10 can be composed of a dielectric material such as, for example, silicon dioxide and/or boron nitride. In other embodiments of the present application, the etch stop layer 10B of the substrate 10 is composed of a third semiconductor material that is compositionally different from the semiconductor material that provides both the first semiconductor material layer 10A and the second semiconductor material layer 10C. In one example, the first semiconductor material layer 10A is composed of silicon, the etch stop layer 10B is composed of silicon dioxide, and the second semiconductor material layer 10C is composed of silicon. In another example, the first semiconductor material layer 10A is composed of silicon, the etch stop layer 10B is composed of silicon germanium, and the second semiconductor material layer 10C is composed of silicon.

The sacrificial placeholder material layer 12L is composed of a fourth semiconductor material that is compositionally different from an uppermost semiconductor material portion of the substrate 10 as well as the semiconductor materials that provide the first sacrificial semiconductor material layers 14L and the first semiconductor channel material layers 16L. In one example, the sacrificial placeholder material layer 12L is composed of a silicon germanium alloy having a germanium content of from 40 atomic percent to 75 atomic percent. Typically, the placeholder material layer 12L has a thickness from 5 nm to 20 nm.

As mentioned above, the first material stack, MS1, includes alternating first sacrificial semiconductor material layers 14L and first semiconductor channel material layers 16L. In some embodiments and as is illustrated in FIGS. 2A-2B, there is an equal number of first sacrificial semiconductor material layers 14L and first semiconductor channel material layers 16L. That is, the first material stack. MS1, can include ‘n’ number of first semiconductor channel material layers 16L and ‘n’ number of first sacrificial semiconductor material layers 14L, wherein n is an integer starting from one. By way of one example, the first material stack MS1 includes three first sacrificial semiconductor material layers 14L and three first semiconductor channel material layers 16L. Each first sacrificial semiconductor material layer 14L is composed of a fifth semiconductor material, while each first semiconductor channel material layer 16L is composed of a sixth semiconductor material that is compositionally different from the fifth semiconductor material; note that the fifth and sixth semiconductor materials are both compositionally different from the fourth semiconductor material.

In some embodiments, the sixth semiconductor material that provides each first semiconductor channel material layer 16L is capable of providing high channel mobility for n-type FET devices. In other embodiments, the sixth semiconductor material that provides each first semiconductor channel material layer 16L is capable of providing high channel mobility for p-type FET devices. The fifth semiconductor material that provides each first sacrificial semiconductor material layer 14L, and the sixth semiconductor material that provides each first semiconductor channel material layer 16L can include one of the semiconductor materials mentioned above for the substrate 10. In one example, each first sacrificial semiconductor material layer 14L is composed of a silicon germanium alloy having a germanium content from 20 atomic percent to 40 atomic percent (note that each first sacrificial semiconductor material layer 14L is compositionally different from the sacrificial placeholder material layer 12L mentioned above), and the sixth semiconductor material that provides each first semiconductor channel material layer 16L is composed of silicon. Other combinations of semiconductor materials are possible as long as the fifth semiconductor material that provides each first sacrificial semiconductor material layer 14L is compositionally different from the sixth semiconductor material that provides each first semiconductor channel material layer 16L, and that the semiconductor materials that provide both the first sacrificial semiconductor material layers 14L and the first semiconductor channel material layers 16L are compositionally different from the semiconductor material that provides the sacrificial placeholder material layer 12L.

Each first sacrificial semiconductor material layer 14L can have a first thickness, and each first semiconductor channel material layer 16L can have a second thickness. In the present application, the first thickness can be equal to, greater than, or less than, the second thickness.

The exemplary structure shown in FIGS. 2A-2B can be formed by first depositing the sacrificial placeholder material layer 12L on the substrate 10, and thereafter second depositing the first material stack, MS1, on the sacrificial placeholder material layer 12L. The second depositing includes forming alternating blanket layers of the fifth semiconductor material and the sixth semiconductor material mentioned above. The first and second depositing can include one of chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° ° C. to 900° C. Although higher temperature typically results in faster deposition, the faster deposition may result in crystal defects and film cracking.

Referring now to FIGS. 3A-3B, there is illustrated the exemplary structure shown in FIGS. 2A-2B, respectively, after forming a hard mask 18 over the first material stack MS1 in the non-stacked transistor device region 100 (shown in FIG. 3A), and recessing the first material stack MS1 in the stacked transistor device region 102 (shown in FIG. 3B) to provide a reduced height first material stack MS1′ in the stacked transistor device region 102.

Hard mask 18 is composed of a hard mask material such as, for example, silicon dioxide, silicon nitride or silicon oxynitride. Hard mask 18 can be formed by deposition of a hard mask material, followed by lithographic patterning. The deposition of the hard mask material can include, for example, CVD, PECVD, physical vapor deposition (PVD), or atomic layer deposition (ALD). Lithographic patterning includes lithography and etching. Lithography includes forming a photoresist material on a material or material stack that needs to be patterned, exposing the photoresist material to a pattern of irradiation, and developing the exposed photoresist material. The etching can include dry etching (i.e., one of reactive ion etching (RIE), ion beam etching (IBE) or plasma etching) and/or chemical wet etching.

The recessing of the first material stack, MS1, in the stacked transistor device region 102 can include a recess etching process. The recess etching process removes at least some, but not all of the first semiconductor channel material layers 16L, and the first sacrificial semiconductor material layers 14L. In some embodiments, the recess etching process stops on a surface of one of the underlying semiconductor channel material layers 16L within the first material stack, MS1. In one example, and as is illustrated in FIG. 3B, two first semiconductor channel material layers 16L and two first sacrificial semiconductor material layers 14L are removed, leaving only a single first semiconductor channel material layer 16L and a single first sacrificial semiconductor material layer 14L in the stacked transistor device region 102.

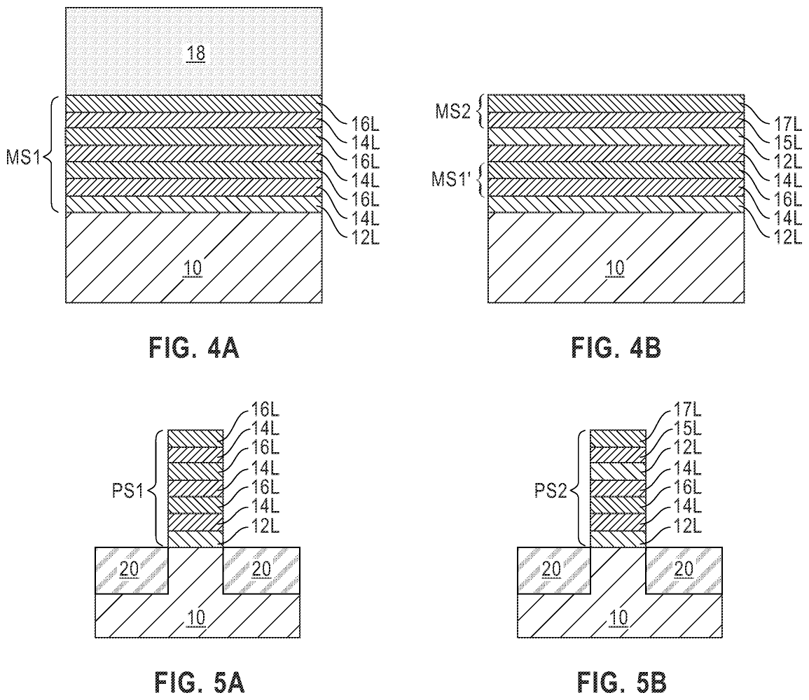

Referring now to FIGS. 4A-4B, there are illustrated the exemplary structure shown in FIGS. 3A-3B, respectively, after forming a first sacrificial semiconductor material layer 14L and another sacrificial placeholder material layer 12L on the reduced height first material stack, MS1′, in the stacked transistor device region 102, and forming a second material stack, MS2, of alternating second sacrificial semiconductor material layers 15L and second semiconductor channel material layers 17L. In some embodiments, in which the recess etch stops on one of the first sacrificial semiconductor material layers 14L, the formation of this additional first sacrificial semiconductor material layer on the reduced height first material stack, MS1′, can be omitted. The first sacrificial semiconductor material layer 14L, the another sacrificial placeholder material layer 12L, and the second material stack, MS2, can be formed utilizing one of the deposition processes mentioned above. The first sacrificial semiconductor material layer 14L and the another sacrificial placeholder material layer 12L that are formed on the reduced height first material stack, MS1′, in the stacked transistor device region 102 include semiconductor materials as mentioned above for the sacrificial placeholder material layer 12L and the first sacrificial semiconductor material layer 14L that were used in forming the exemplary structure shown in FIGS. 2A-2B.

In the second material stack, MS2, of alternating second sacrificial semiconductor material layers 15L and second semiconductor channel material layers 17L, there is an equal number of second sacrificial semiconductor material layers 15L and second semiconductor channel material layers 17L. That is, the second material stack, MS2, can include ‘m’ number of second semiconductor channel material layers 17L and ‘m’ number of second sacrificial semiconductor material layers 15L, wherein m is an integer starting from one. By way of one example, the second material stack MS2 includes one second sacrificial semiconductor material layer 15L and one second semiconductor channel material layer 17L. Each second sacrificial semiconductor material layer 15L is composed of the fifth semiconductor material mentioned above, while each second semiconductor channel material layer 17L is composed of a seventh semiconductor material that is compositionally different from the fifth semiconductor material. In the present application, the seventh semiconductor material can be compositionally the same or compositionally different from the sixth semiconductor material. The seventh semiconductor material is compositionally different from the fourth semiconductor material that provides each of the sacrificial placeholder material layers 12L shown in FIG. 4B. The seventh semiconductor material can be selected to provide enhanced channel mobility p-type or n-type transistors.

In embodiments of the present application, the number of first sacrificial semiconductor material layers 14L in the first material stack, MS1, in the non-stacked transistor device region 100, can be equal to, or greater than, the total number of first sacrificial semiconductor material layers 14L and second semiconductor channel material layers 17 that are present in the reduced height first material stack, MS1′, and the second material stack, MS2, in the non-stacked transistor device region 102. It is noted that in the present application, a topmost surface of the first material stack, MS1, in the non-stacked transistor device region 100, is coplanar with a topmost surface of the semiconductor material stack, MS2, in the stacked transistor device region 102.

Referring now to FIGS. 5A-5B, there are illustrated the exemplary structure shown in FIGS. 4A-4B, respectively, after removing the hard mask 18 over the first material stack, MS1, in the non-stacked transistor device region 100, patterning the first material stack, MS1, and the sacrificial placeholder material layer 12L in the non-stacked transistor device region 100 to provide a first patterned material stack, PS1, patterning the second material stack, MS2, the another sacrificial placeholder material layer 12L, the first sacrificial semiconductor material layer 14L and the reduced height first material stack, MS1′, in the stacked transistor device region 102 to provide a second patterned material stack, PS2, and forming a shallow trench isolation structure 20 in the substrate 10 and at the footprint of both the first and second patterned material stacks, PS1 and PS2.

The hard mask 18 can be removed utilizing a material removal process such as, for example, planarization (e.g., chemical mechanical polishing (CMP)) or etching. The patterning in each of the device regions typically occurs simultaneously using lithographic patterning as defined above. In embodiments, patterning of one of the device regions can be performed prior to patterning the other device region. The number of patterned material stacks in each device region can vary as long as one first patterned material stack, PS1, and one second patterned material stack, PS2, are formed in the respective device region. In the present application, the first patterned material stack, PS1, that is present in the non-stacked transistor device region 100 (See, FIG. 5A) includes a remaining (i.e., non-etched) portion of the sacrificial placeholder material layer 12L and a remaining (i.e., non-etched) portion of the first material stack, MS1. In the present application, the second patterned material stack, PS2, that is present in the stacked transistor device region 102 (See, FIG. 5B) includes a remaining (i.e., non-etched) portion of the sacrificial placeholder material layer 12L, a remaining (i.e., non-etched) portion of the reduced height first material stack, MS1′, a remaining (i.e., non-etched) portion of both the first sacrificial semiconductor material layer 12L and the another sacrificial placeholder material layer 12L, and a remaining (i.e., non-etched) portion of the second material stack, MS2.

The shallow trench isolation structure 20 is composed of any trench dielectric material such as, for example, silicon oxide. In some embodiments, a trench dielectric liner composed of, for example, SiN, can be present along a sidewall and a bottom wall of the trench dielectric material. The shallow trench isolation structure 20 can have a topmost surface that is coplanar with a topmost surface of the non-etched portion of the substrate 10. The shallow trench isolation structure 20 can be formed by first forming (by lithography and etching) a trench in an upper portion of the substrate 10, depositing the optional trench dielectric liner material and the trench dielectric material in the trench, and thereafter performing an etch back process.

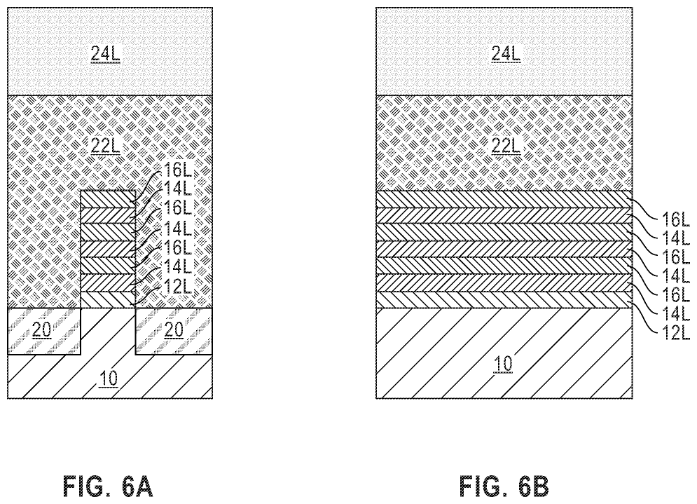

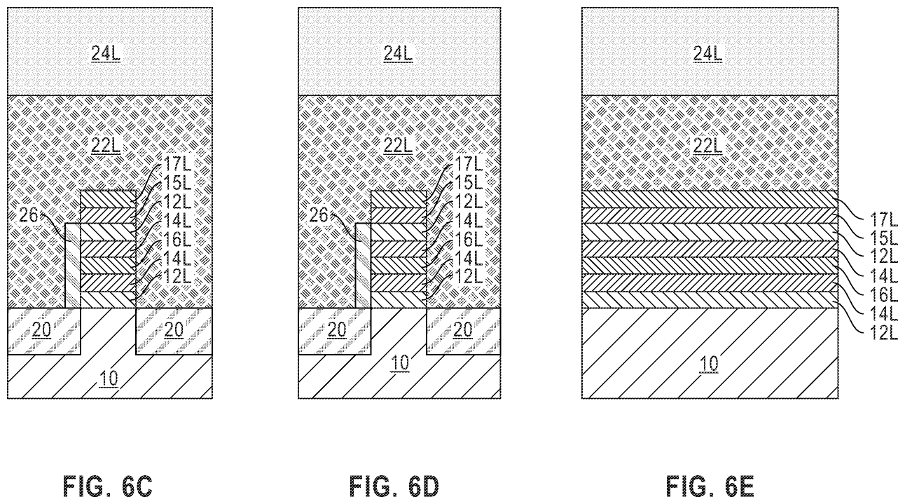

Referring now to FIGS. 6A-6E, there are illustrated the exemplary structure shown in FIGS. 5A-5B after forming a sacrificial spacer 26 on one side of the second patterned material stack, PS2, and forming a sacrificial gate material layer 22L, and a sacrificial hard mask layer 24L in both the non-stacked transistor device region 100 and the stacked transistor device region 102.

The sacrificial spacer 26 can be composed of the fourth semiconductor material that was mentioned above in regard to the sacrificial placeholder material layer 12L or a metal oxide such as, for example, TiO_{X}. Typically, the sacrificial spacer 26 is composed of a fourth semiconductor material that is compositionally the same as that used in providing the sacrificial placeholder material layer 12L; this aids in a single step removal of sacrificial placeholder material layers 12L and the sacrificial spacer 26. The sacrificial spacer 26 can be formed by deposition, followed by a spacer etch; block mask technology can be used to protect the non-stacked transistor device region 100 during sacrificial spacer 26 formation. The sacrificial spacer 26 has a topmost surface that is substantially (within +10%) coplanar with a topmost surface of the another sacrificial placeholder material layer 12L that is present in the second patterned material stack, PS2.

After sacrificial spacer 26 formation, the sacrificial gate material layer 22L and the sacrificial hard mask layer 24L are formed. The sacrificial gate material layer 22L includes at least a sacrificial gate material. In some embodiments, sacrificial gate material layer 22L can also include a sacrificial gate dielectric material. The optional sacrificial gate dielectric material can be composed of a dielectric material such as, for example, silicon dioxide. The sacrificial gate material can include, but is not limited to, polysilicon, amorphous silicon, amorphous silicon germanium or amorphous germanium. The sacrificial hard mask layer 24L is composed of one of the hard mask materials mentioned above for the hard mask 18.

The sacrificial gate material layer 22L and the sacrificial hard mask layer 24L can be formed utilizing a deposition process such as, for example, CVD, PECVD, PVD, or ALD. In the present application, the sacrificial gate material layer 22L is deposited prior to depositing the sacrificial hard mask layer 24L. In some embodiments, the formation of the sacrificial hard mask layer 24L can be omitted.

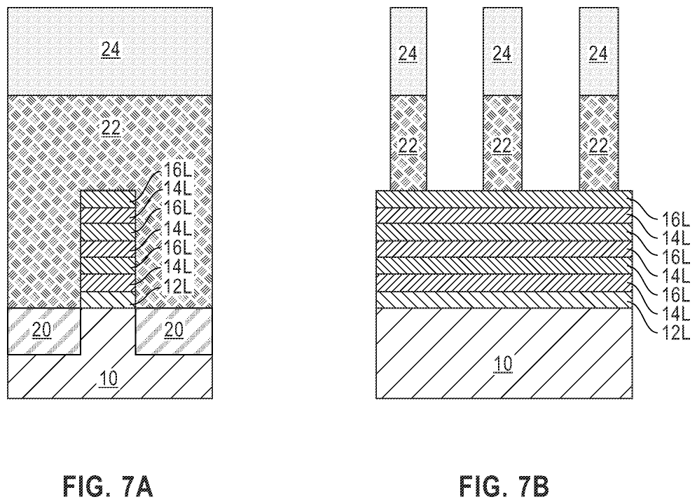

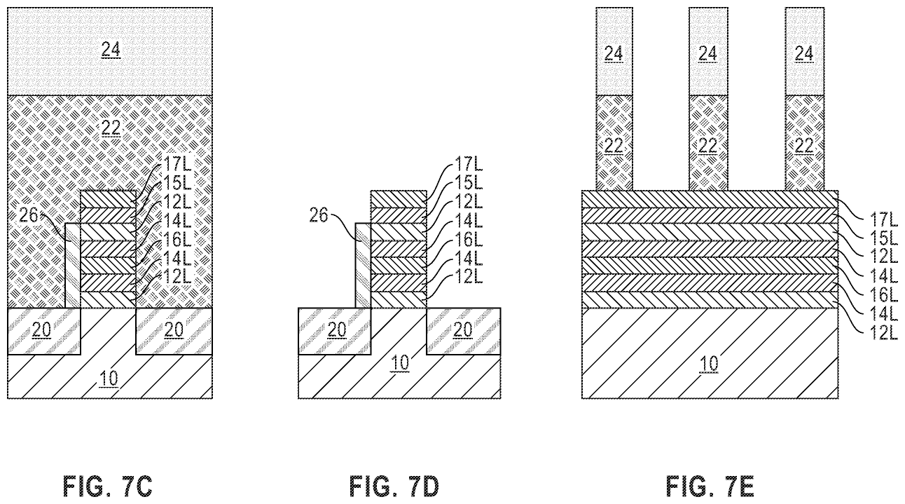

Referring now to FIGS. 7A-7E, there are illustrated the exemplary structure shown in FIGS. 6A-6E, respectively, after patterning the sacrificial hard mask layer 24L and the sacrificial gate material layer 22L to provide hard mask capped sacrificial gate structures in both the non-stacked transistor device region 100 and the stacked transistor device region 102. The number of hard mask capped sacrificial gate structures can vary in each device region so long as at least one hard mask capped sacrificial gate structure is formed in each of the device regions. Each hard mask cap sacrificial gate structure includes a remaining (i.e., non-etched) portion of the sacrificial gate material layer 22L (hereinafter after sacrificial gate structure 22) and a remaining (i.e., non-etched) portion of the sacrificial hard mask layer 24L (hereinafter sacrificial gate mask 24). Patterning includes lithography and etching. Note that the sacrificial gate mask 24 typically has a sidewall that is vertically aligned to a sidewall of the sacrificial gate structure 22. As is illustrated in FIG. 7A, the hard mask capped sacrificial gate structure in the non-stacked transistor device region 100 is located on top of, and along opposing sidewalls of, the first patterned material stack, PS1. As is illustrated in FIG. 7C, the hard mask capped sacrificial gate structure in the stacked transistor device region 102 is located on top of, and along opposing sidewalls, of the second patterned material stack, PS2.

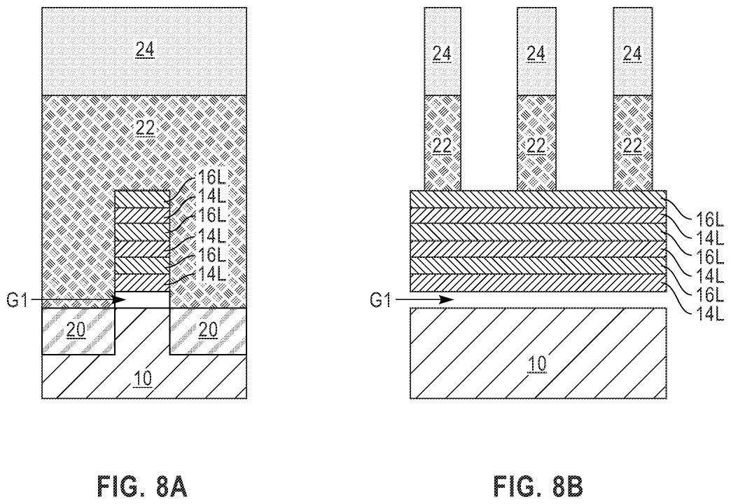

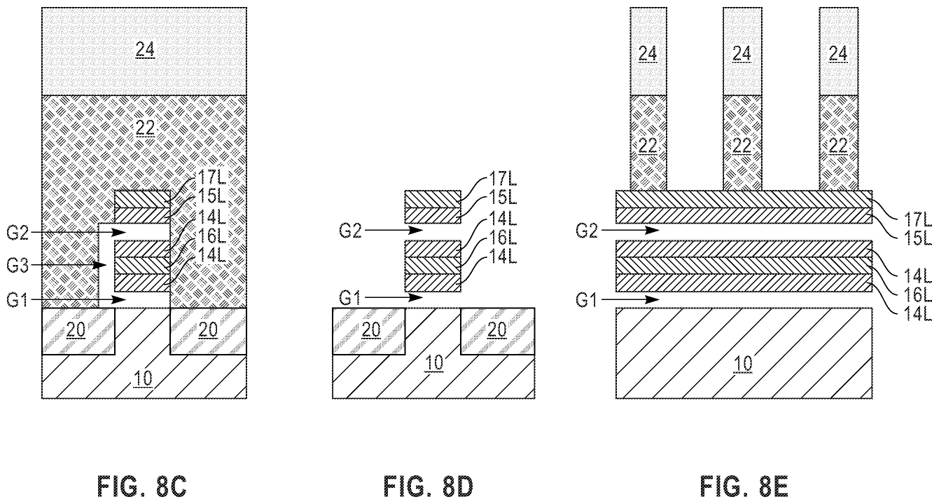

Referring now to FIGS. 8A-8E, there are illustrated the exemplary structure shown in FIGS. 7A-7E, respectively, after removing the remaining sacrificial placeholder material layer 12L from the first patterned material stack, PS1, and the from the second patterned material stack. PS2, and also removing the sacrificial spacer 26. The removal of the remaining sacrificial placeholder material layers 12L, and the sacrificial spacer 26 can be performed simultaneously utilizing one of more chemical wet etching process. The removal of the remaining sacrificial placeholder material layer 12L from the first patterned material stack, PS1, forms a first gap, G1 in the first patterned material stack, PS1, and removal of the sacrificial spacer 26 and the remaining sacrificial placeholder material layers 12L from the second patterned material stack, PS2, forms a first gap, G1, a second gap, G2 and a third gap, G3, in the second patterned material stack, PS2. Note that G1, G2 and G3 are interconnected as is shown in FIG. 8C. Also, note that the remaining first and second patterned material stacks, PS1 and PS2, are not free floating, since the patterned hard mask capped sacrificial gate structures serves as an anchoring element.

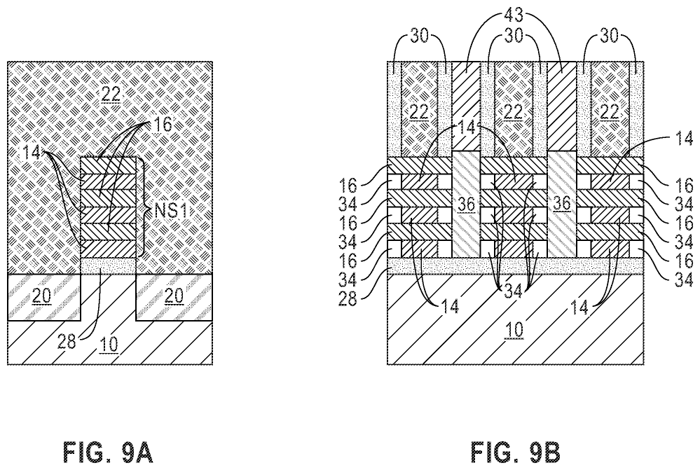

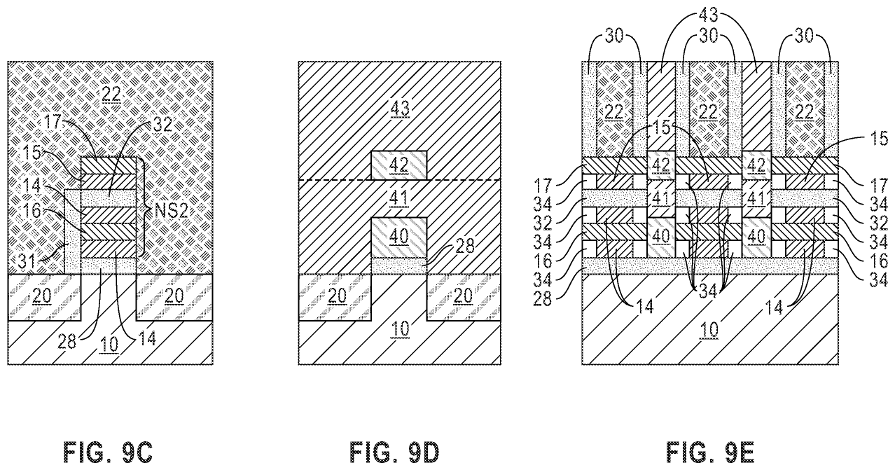

Referring now to FIGS. 9A-9E, there are illustrated the exemplary structure shown in FIGS. 8A-8E, respectively, after nanosheet device processing. The nanosheet device processing can include forming, at a same time, a gate dielectric spacer 30 along sidewalls of the hard mask capped sacrificial gate structures in both the non-stacked transistor device region 100 and the stacked device region 102, a bottom dielectric isolation layer 28 in each first gap, G1, a middle dielectric isolation layer 32 in the second gap, G2, and a stacked device gate spacer 31 in the third gap, G3. The gate dielectric spacer 30, each bottom dielectric isolation layer 28, the middle dielectric isolation layer 32, and the stacked device gate spacer 31 are all composed of a same dielectric spacer material such as, for example, silicon dioxide, SiN, SiBCN, SiOCN or SiOC. The gate dielectric spacer 30, each bottom dielectric isolation layer 28, the middle dielectric isolation layer 32, and the stacked device gate spacer 31 can be formed by a deposition process such as, for example, CVD, PECVD, or ALD.

After forming the gate dielectric spacer 30, each bottom dielectric isolation layer 28, the middle dielectric isolation layer 32, and the stacked device gate spacer 31, the first patterned material stack, PS1, is converting into a first nanosheet containing stack, NS1, and the second patterned material stack, PS2, is converted into a second nanosheet containing stack, NS2. This converting includes etching utilizing at least each gate dielectric spacer 32/sacrificial gate structure 22 combination as an etch mask. The etch can include a reactive ion etch. The term “nanosheet containing stack” denotes that the various material layers that are present in the stack are nanosheets. In the first nanosheet containing stack, NS1, each remaining first sacrificial semiconductor material layer 14L can be referred to a first sacrificial semiconductor material nanosheet 14, and each remaining first semiconductor channel material layer 16L can be referred to as a first semiconductor channel material nanosheet 16. In the second nanosheet containing stack, NS1, each remaining first sacrificial semiconductor material layer 14L can be referred to a first sacrificial semiconductor material nanosheet 14, each remaining first semiconductor channel material layer 16L can be referred to as a first semiconductor channel material nanosheet 16, each remaining second sacrificial semiconductor material layer 15L can be referred to as a second sacrificial semiconductor material nanosheet 15, and each remaining second semiconductor channel material 17L can be referred to as a second semiconductor channel material nanosheet 17.

Next, each sacrificial semiconductor material nanosheet present in the first and second nanosheet containing stacks, NS1, and NS2, are recessed utilizing a recess etching process. The recess etching process is a lateral etching process that is selective for removing a portion of each sacrificial semiconductor material nanosheet. Note that the recessed sacrificial semiconductor material nanosheets have a width that is less than a width of each of the semiconductor channel material nanosheets present in the first and second nanosheet containing stacks, NS1, and NS2.

Next, an inner spacer 34 is formed laterally adjacent to each recessed semiconductor material nanosheet present in the first and second nanosheet containing stacks, NS1, and NS2. Each inner spacer 34 is composed of one of dielectric spacer materials mentioned above for forming the gate dielectric spacer 30, each bottom dielectric isolation layer 28, the middle dielectric isolation layer 32, and the stacked device gate spacer 31. The dielectric spacer material that provides each inner spacer 34 can be compositionally the same as, or compositionally different from, the dielectric material that provides the gate dielectric spacer 30, each bottom dielectric isolation layer 28, the middle dielectric isolation layer 32, and the stacked device gate spacer 31. The inner spacer 34 is formed by deposition and etching.

Source/drain regions and first frontside ILD material layers are now formed in each of the device regions. Notably, non-stacked device source/drain regions 36 are formed in the non-stacked transistor device region 100 (See, FIG. 9B) which extend outward from a sidewall of each first semiconductor channel material nanosheet 16 of the first nanosheet containing stack, NS1, and first ILD material layer 38 is formed on the non-stacked device source/drain regions 36. Bottom source/drain regions 40 are formed in the stacked transistor device region 102 (See, FIG. 9E) which extend outward from a sidewall of each first semiconductor channel material nanosheet 16 of the second nanosheet containing stack, NS2, and top source/drain regions 42 are formed in the stacked transistor device region 102 (See, FIG. 9E) which extend outward from a sidewall of each second semiconductor channel material nanosheet 17 of the second nanosheet containing stack. NS2. The top source/drain regions 42 are separated from the bottom source/drain regions 40, by dielectric material layer 41. Next, another first ILD material layer 43 is formed on top of an adjacent to each top source/drain regions 42. First ILD material layer 38 and the another first ILD material layer 43 are both frontside ILD material layers.

In the present application, the source/drain regions and first frontside ILD material layer formation within the stacked transistor device region 100 can occur prior to or after forming the source/drain regions and first frontside ILD material layer in the stacked transistor device region 102. The separate processing can be achieved utilizing block mask technology.

Each of the source/drain regions, including the non-stacked device source/drain regions 36, the bottom source/drain regions 40, and the top source/drain regions 42 is composed of a semiconductor material and a dopant. As used herein, a “source/drain” region can be a source region or a drain region depending on subsequent wiring and application of voltages during operation of the transistor. The semiconductor material that provides each of the source/drain regions, including the non-stacked device source/drain regions 36, the bottom source/drain regions 40, and the top source/drain regions 42 is composed of one of the semiconductor materials mentioned above for the substrate 10. The semiconductor material that provides the source/drain regions can be compositionally the same, or compositionally different from each semiconductor channel material nanosheet that the source/drain region contacts. The semiconductor material that provides each source/drain region is however compositionally different from each recessed sacrificial semiconductor material nanosheet. The dopant that is present in the source/drain regions can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the source/drain regions can have a dopant concentration of from 4×10²⁰ atoms/cm³ to 3×10²¹ atoms/cm³. In some embodiments, the dopant within the top source/drain regions 42 is of a same conductivity type as the dopant within the bottom source/drain regions 40. In other embodiments, the dopant within the top source/drain regions 42 is of a different conductivity type as the dopant within the bottom source/drain regions 40. Thus, and in the stacked transistor device region 102, transistor of the same conductivity type or different conductivity types can be formed. That is, in the stacked transistor device region 102, two vertically stacked nFETs can be formed, or two vertically stacked pFETs can be formed, or an nFET stacked over a pFET can be formed, or a pFET stacked over an n-FET can be formed. Different conductivity type transistors can also be formed in the non-stacked transistor device region.

Dielectric material layer 41, first ILD material layer 38 that is present in the non-stacked transistor device region 100, and the another first ILD material layer 43 that is formed in the stacked transistor device region 102 can be formed utilizing a deposition process (CVD, PECVD, ALD or spin-on coating), followed by a recess etch (in the case of the dielectric material layer 41 formation) and/or a planarization process (in the case of the ILD material layers 38, 43). Dielectric material layer 41, first ILD material layer 38 that is present in the non-stacked transistor device region 100, and the another first ILD material layer 43 that is present in the stacked transistor device region 102 are each composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The dielectric material that provides the dielectric material layer 41 can be compositionally the same as, or compositionally different from, the dielectric material that provides the another first ILD material layer 43. The dielectric material that provides the first ILD material layer 38 can be compositionally the same as, or compositionally different from, the dielectric material that provides the another first ILD material layer 43. In the drawings, a dotted line is shown to represent that a material interface can exist between this various dielectric materials.

As is illustrated, the planarization process that follows the deposition process that provides the first ILD material layers in the respective device regions, removes the sacrificial gate cap 24 and an upper portion of each dielectric gate spacer 30.

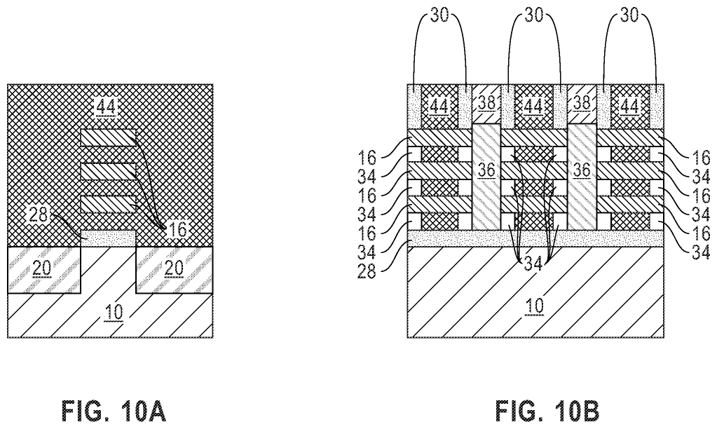

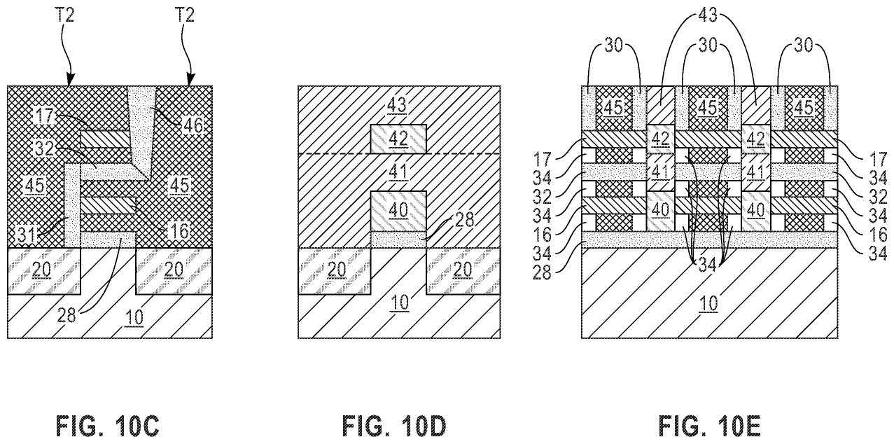

Referring now to FIGS. 10A-10E, there are illustrated the exemplary structure shown in FIGS. 9A-9E, respectively, after gate processing which includes removing the sacrificial gate structure 22 to reveal the nanosheet containing material stacks (i.e., NS1 or NS2) in the respective device region, removing the recessed sacrificial semiconductor material nanosheets (14 or 14/15) from the revealed nanosheet containing stack, forming a gate structure (44, 45), and forming a dielectric gate cut pillar 46 cutting the gate structure 45 in the stacked transistor device region 102. In the present application, gate structure 44 is formed in the non-stacked transistor device region 100, while gate structure 45 is formed in the stacked transistor device region 102. In FIG. 10C, T1 denotes a first (or bottom) transistor of a stacked transistor device, and T2 denotes a second (or top) transistor of the stacked transistor device.

In the present application, the gate processing can be performed in the non-stacked device region 100 at the same time, or prior to, or after gate processing in the stacked device region 102. Gate processing at different times can be achieved utilizing block mask technology. Each sacrificial gate structure 22 can be removed by an etching process such as, for example, reactive ion etching. Next, each recessed sacrificial semiconductor material nanosheet (14, 15) can be removed utilizing at least one material removal process that is selective in removing the sacrificial semiconductor material nanosheets (14, 15).

Gate structures 44, 45 are then formed. Gate structures 44, 45 include a gate dielectric material and a gate electrode, both of which are not separately shown, but intended to be within region defined by the gate structures 44, 45. As is known to those skilled in the art, the gate dielectric material directly contacts a physically exposed surface(s) of each semiconductor channel material nanosheet, and the gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOxNy), tantalum oxide (TaOx), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). In embodiments of the present application, gate structure 44 can be compositionally the same as, or compositionally different from, gate structure 45. The gate structure 44, 45 can be formed by deposition of the gate dielectric material, and gate electrode material, followed by a planarization process. Note that gate structure 44 has same height as gate structure 45 and that gate structure 44 has a bottommost surface that is coplanar with a bottommost surface of gate structure 45, and that gate structure 44 topmost surface that is coplanar with a topmost surface of gate structure 45.

Dielectric gate cut pillar 46 can be formed by forming an opening in the gate structure 45, and then filling (including deposition and planarization) that opening with one of the dielectric materials mentioned above for providing the gate dielectric spacer 30, each bottom dielectric isolation layer 28, the middle dielectric isolation layer 32, and the stacked device gate spacer 31. Typically, the dielectric gate cut pillar 46 is composed of a compositionally same dielectric material as that used in providing the gate dielectric spacer 30, each bottom dielectric isolation layer 28, the middle dielectric isolation layer 32, and the stacked device gate spacer 31. In the stacked transistor device region 102, the dielectric gate cut pillar 46, the middle dielectric isolation layer 32, the stacked device gate spacer 31, and the bottom dielectric isolation layer 28 collectively provide a continuous dielectric structure. Within this continuous dielectric structure, a first end of the middle dielectric isolation layer 32 is connected to the dielectric gate cut pillar 46, and a second end of the middle dielectric isolation layer 32 is connected to the bottom dielectric isolation layer 28 by the stacked device gate spacer 31. In the present application, the middle dielectric isolation layer 32 and the bottom dielectric isolation layer 28 are orientated parallel to each semiconductor material nanosheet 16, 17, and the dielectric gate cut pillar 46 and the stacked device gate spacer 31 are orientated perpendicular to each semiconductor material nanosheet 16, 17. In the drawings, a dotted line is shown in this dielectric structure to emphasize each element that provides that structure.

These steps form a non-stacked transistor (including gate structure 44 wrapped around the vertical stacked of first semiconductor nanosheets 16, and source/drain regions 36 located on each side of the gate structure 44) in the non-stacked device region 100, and a first transistor (including gate structure 45 wrapped around the first semiconductor channel material nanosheets 14, and bottom source/drain regions 40) and a second transistor (including gate structure 45 wrapped around the second semiconductor channel material nanosheet 17, and top source/drain regions 42) in the stacked transistor device region 102, wherein the second transistor is stacked above the first transistor.

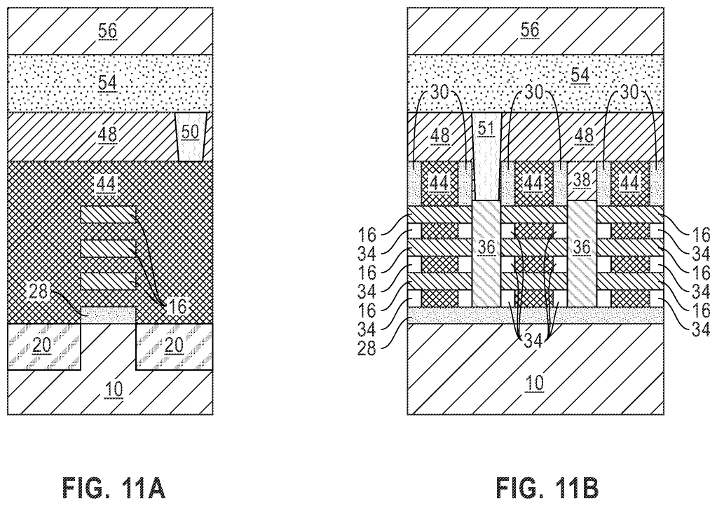

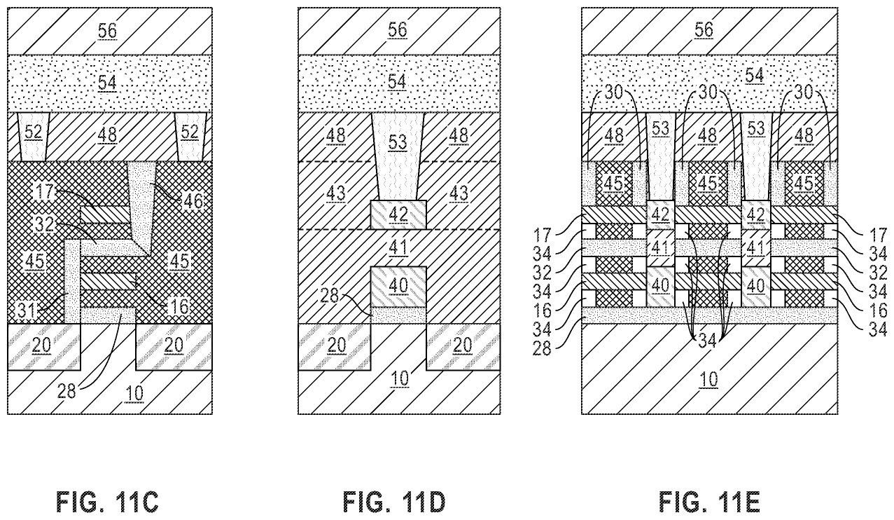

Referring now to FIGS. 11A-11E, there are illustrated the exemplary structure shown in FIGS. 10A-10E, respectively, after forming a frontside interconnect including frontside contact structures 50, 51, 52, 53, a frontside BEOL structure 54 and a carrier wafer 56. Each frontside contact structures 50, 51, 52, 53 is located in a second frontside ILD material layer 48.

In the present application, the second frontside ILD material layer 48 is first formed utilizing one of the deposition processes mentioned above in forming the ILD material layers 38, 43. The second frontside ILD material layer 48 can include one of the dielectric materials mentioned above for the ILD material layers 38, 43. The dielectric material that provides second frontside ILD material layer 48 can be compositionally the same as, or compositionally different from, the dielectric material that provides the first ILD material layer 38 and/or the another first ILD material layer 43. The various frontside ILD material layers can provide a multilayered frontside ILD material structure.

Frontside contact structures 50, 51, 52, 53 are then formed utilizing a metallization process that includes forming frontside contact openings in the at least one frontside ILD material layer, and thereafter filling (including deposition and planarization) each frontside contact opening with at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures 50, 51, 53 can also include one or more contact liners (not shown). In one or more embodiments, the contact liner (not shown) can include a diffusion barrier material. Exemplary diffusion barrier materials include, but are not limited to, Ti, Ta, Ni, Co, Pt. W. Ru. TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. In the present application, frontside contact structure 50 contacts the gate structure 44 of the non-staked transistor and electrically connects the gate structure 44 to the frontside BEOL structure 54. Frontside contact structure 50 can thus be referred to as a gate contact structure located in the non-stacked device region 100. Frontside contact structure 51 contacts one of the source/drain regions 36 of the non-stacked transistor and electrically connects this source/drain region to the frontside BEOL structure 54. Frontside contact structure 51 can thus be referred to as a source/drain contact structure located in the non-stacked device region 100. Frontside contact structures 52 contact gate structure 45 of the first and second transistors and electrically connects those two gate structure 45 to the frontside BEOL structure 54. Frontside contact structures 52 can thus be referred to as a gate contact structure located in the stacked device region 102. Frontside contact structures 53 contacts the top source/drain regions 42 of the second transistor and electrically connects those source/drain regions to the frontside BEOL structure 54. Frontside contact structures 53 can thus be referred to as a top source/drain contact structures located in the stacked device region 102.

The frontside BEOL structure 54 can include one or more interconnect dielectric material layers (including one of the dielectric materials mentioned above for the first frontside ILD material layers 38, 48 that contain one or more wiring regions (the wiring regions can include any electrically conductive metal or metal alloy) embedded therein. The frontside BEOL structure 54 can be formed utilizing any interconnect device processing technique. In some embodiments, the wiring regions are Cu wiring regions. The carrier wafer 56 can include one of the semiconductor materials mentioned above for the first semiconductor material layer 10. Carrier wafer 56 is bonded to the frontside BEOL structure 54 after frontside BEOL structure 54 formation.

Referring now to FIGS. 12A-12E, there are illustrated the exemplary structure shown in FIGS. 11A-11E, respectively, after flipping the wafer 180° to physically expose a backside of the substrate 10; in these drawings the substrate 10 includes first semiconductor material layer 10A, etch stop layer 10B, and second semiconductor material layer 11C. Thus, this flipping can physically expose the first semiconductor layer 10C of the substrate 10. This flipping step will allow backside processing of the exemplary structure. Backside processing occurs on a side of a wafer opposite the side where the transistors have been formed. Flipping of the structure can be performed by hand or by utilizing a mechanical means such as, for example, a robot arm.

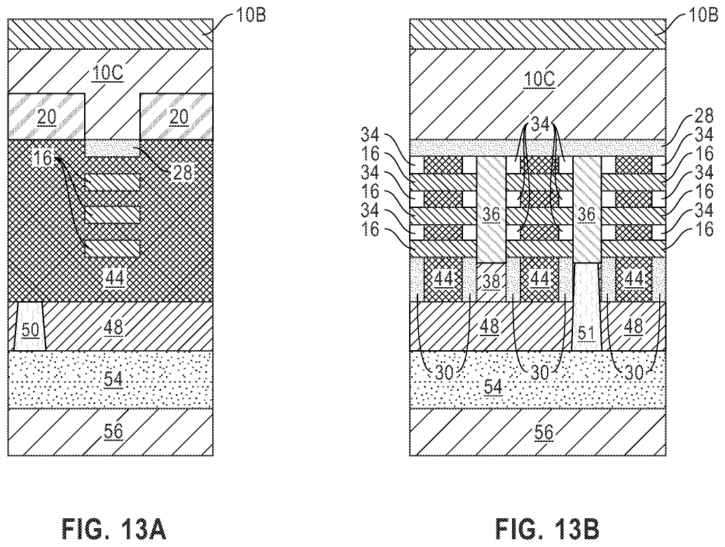

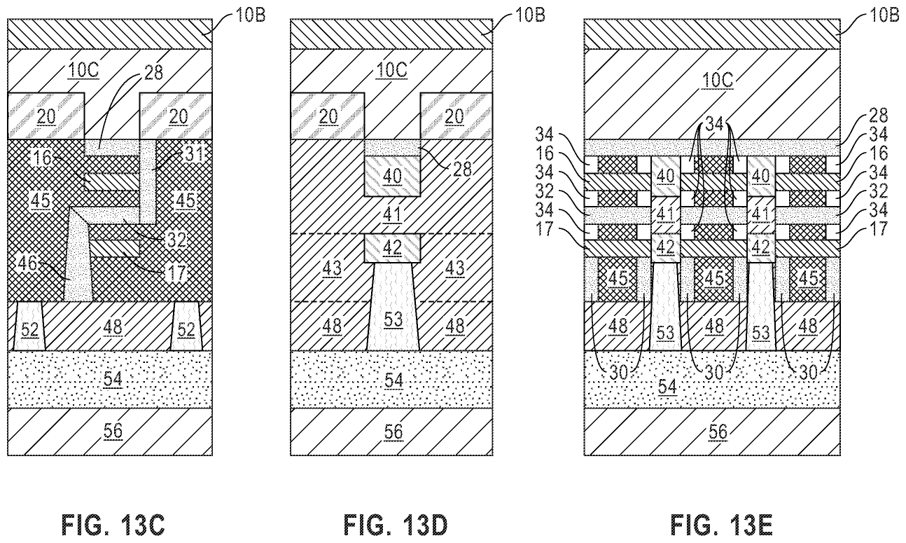

Referring now to FIGS. 13A-13E, there are illustrated the exemplary structure shown in FIGS. 12A-12E, respectively, after removing the physically exposed first semiconductor material layer 10C of the substrate 10 to physically expose the etch stop layer 10B of the substrate 10. The removal of the first semiconductor material layer 10A of the substrate 10 can be performed utilizing a material removal process that is selective in removing the first semiconductor material that provides the first semiconductor material layer 10A.

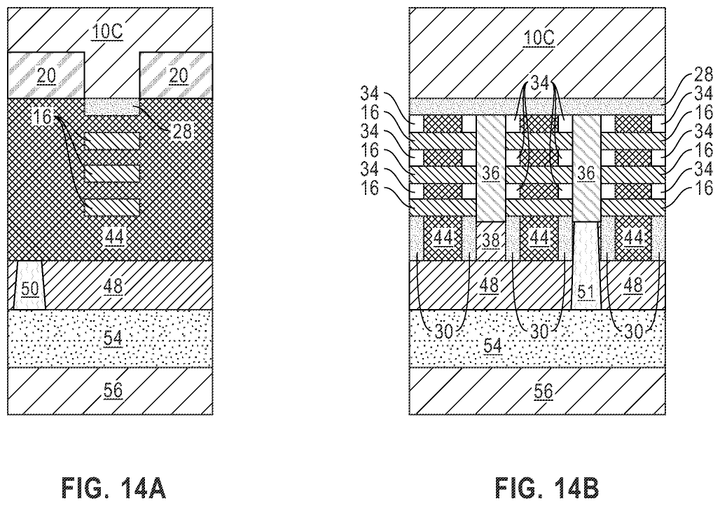

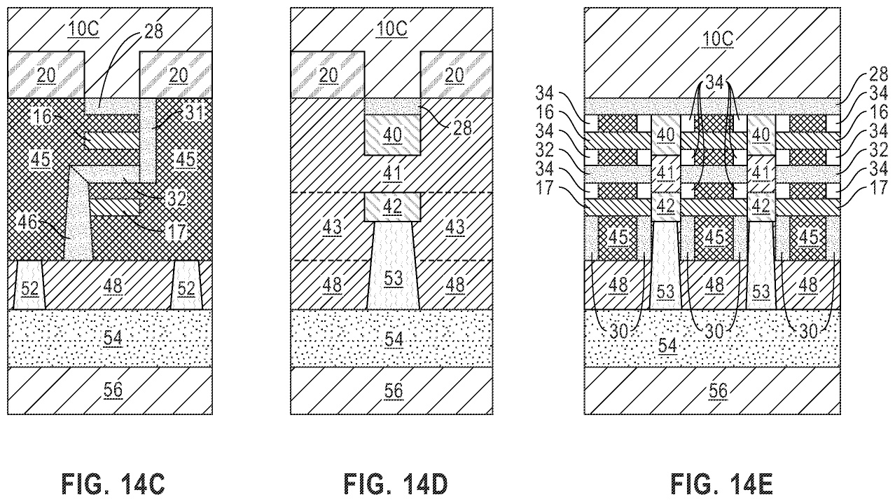

Referring now to FIGS. 14A-14E, there are illustrated the exemplary structure shown in FIGS. 13A-13E, respectively, after removing the physically exposed etch stop layer 10B of the substrate 10 to physically expose the second semiconductor material layer 10C of the substrate 10. The removal of the etch stop layer 10B includes a material removal process that is selective in removing the etch stop layer 10B.

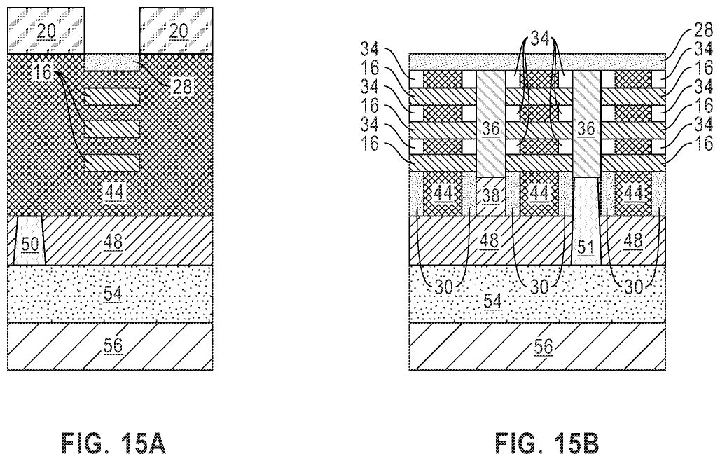

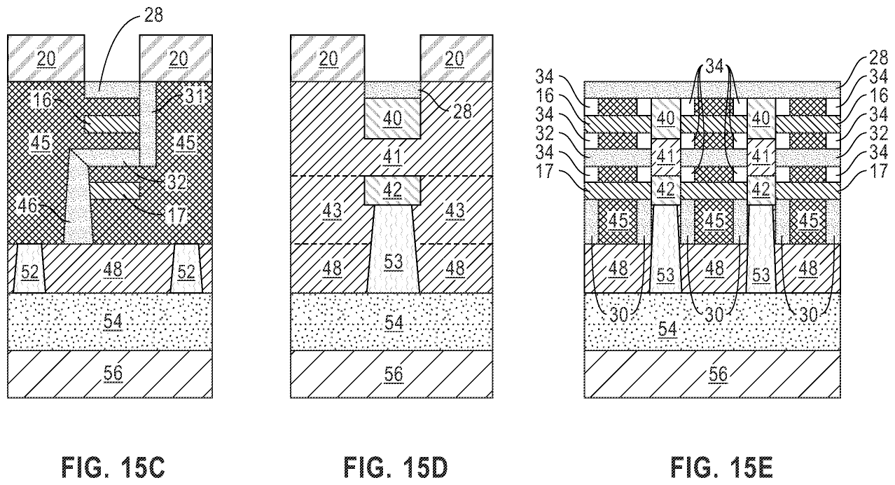

Referring now to FIGS. 15A-15E, there are illustrated the exemplary structure shown in FIGS. 14A-14E, respectively, after removing the physically exposed second semiconductor material layer 10C of the substrate 10. Note that in some embodiments in which substrate 10 is a composed entirely of one semiconductor material, one material removal process can be used instead of the multiple material removal processing steps described in FIGS. 13A-15E. The physically exposed second semiconductor material layer 10C of the substrate 10 can be removed utilizing a material removal process that is selective in removing that layer from the structure.

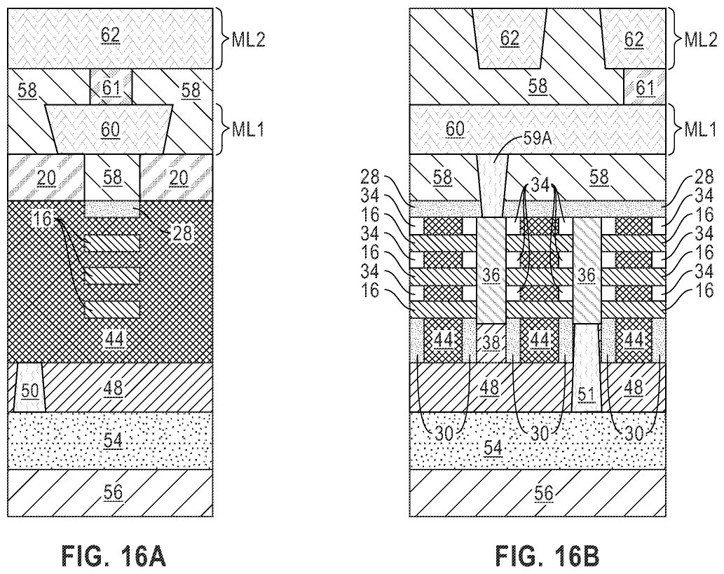

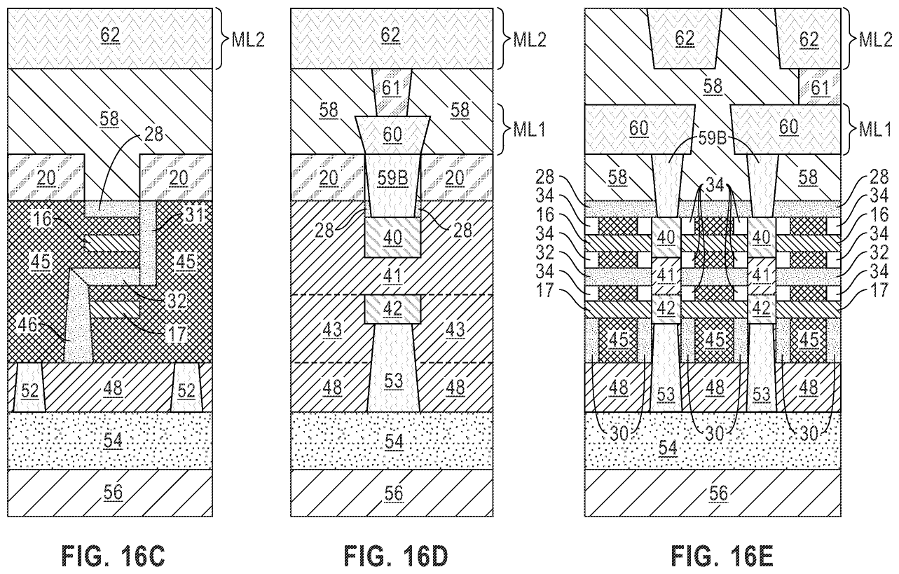

Referring now to FIGS. 16A-16E, there are illustrated the exemplary structure shown in FIGS. 15A-15E, respectively, after forming a backside interconnect including a first backside metal level, M1, including a plurality of first backside electrically conductive structures 60, and a second backside metal level, M2, located on the first backside metal level, M1, and including a plurality of second backside electrically conductive structures 62. A via level include via structures 61 is located between the first and second metal levels; in the present application the via structures 61 can be used to electrically connect the first metal level to the second metal level. Notably, via structure 61 can electrically connects one of the second backside electrically conductive structures 62 to one of the first backside electrically conductive structures 60.

In the present application, one of the first backside electrically conductive structures 60 is electrically connected to another source/drain region 36 of the transistor in the non-transistor device region 100 by a first backside source/drain contact structure 59A, and at least two other first backside electrically conductive structures 60 are electrically connected to bottom source/drain regions (i.e., source/drain regions 40) of a bottom transistor of in the stacked transistor device region 102 by a second backside source/drain contact structure 59B.

Each of the first backside source/drain contact structure 59A, the second backside source/drain contact structures 59B, the plurality of first backside electrically conductive structures 60, the via structures 61 and the plurality of second backside electrically conductive structures 62 is embedded in a multilayered backside ILD material structure 58. The multilayered backside ILD material structure 58 includes multiple dielectric materials (including one of the dielectric materials mentioned above for the various frontside ILD material layers).

Each of the first backside source/drain contact structure 59A, the second backside source/drain contact structures 59B, the plurality of first backside electrically conductive structures 60, the via structures 61 and the plurality of second backside electrically conductive structures 62 can be formed by a metallization process as described above, and each of the second backside source/drain contact structures 59B, the plurality of first backside electrically conductive structures 60, the via structures 61 and the plurality of second backside electrically conductive structures 62 is composed of at least a contact conductor material (and any of the optional materials) mentioned above for the frontside contact structures 50, 51, 52, 53.

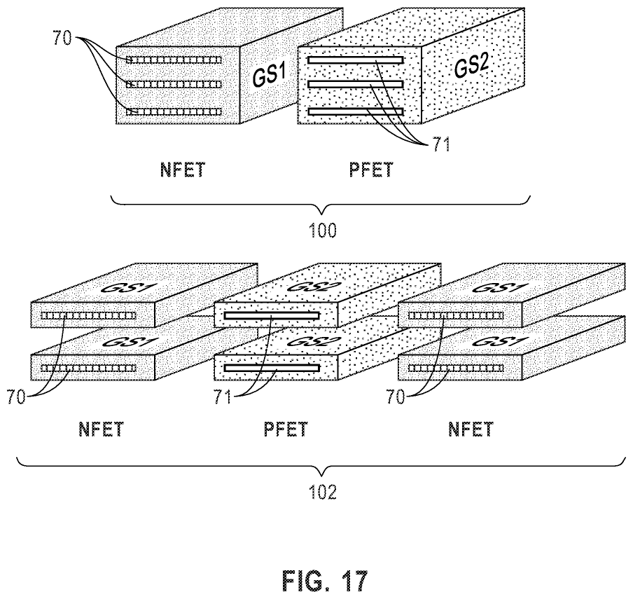

The various embodiments of the present application as described above provide a structure as shown in FIG. 17 that combines a high performance, low density device (e.g., logic devices), with a low performance, high density device (e.g., SRAM device). Notably, FIG. 17 illustrates a semiconductor structure in accordance with the present application including a non-stacked transistor device region 100 including a full height nanosheet logic nFET and a full height nanosheet logic pFET, and a stacked transistor device region 102 including reduced height stacked nanosheet SRAM FETs. For clarity, the frontside and backside interconnects are not shown in FIG. 17. The full height nanosheet logic nFET includes nFET semiconductor channel material nanosheets 70 and an nFET gate structure, GS1, and the full height nanosheet logic pFET includes pFET semiconductor channel material nanosheets 71 and a pFET gate structure, GS2. The reduced height stacked nanosheet SRAM FETs including a pair of stacked nFETs including nFET semiconductor channel material nanosheets 70 and nFET gate structures, GS1, and a stacked pFET including pFET semiconductor channel material nanosheets 71 and pFET gate structures, GS2. The nFET and pFET semiconductor channel material nanosheets 70, 71 comprise a semiconductor material as mentioned above, and the nFET gate structures, GS1, and the pFET gate structures, GS2, including a gate dielectric material and a gate electrode as mentioned above.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a non-stacked transistor having a frontside and a backside;
a stacked transistor located laterally adjacent to the non-stacked transistor and having a frontside and a backside, the stacked transistor comprising two or more transistors stacked one atop the other;
a frontside interconnect located on the frontside of both the non-stacked transistor and the stacked transistor; and
a backside interconnect located on the backside of both the non-stacked transistor and the stacked transistor.

2. The semiconductor structure of claim 1, wherein the frontside interconnect comprises a multilayered frontside interlayer dielectric (ILD) material structure having frontside contact structures embedded therein, and a frontside back-end-of-the-line (BEOL) structure located on the multilayered frontside ILD material structure.

3. The semiconductor structure of claim 2, further comprising:
a carrier wafer located on the frontside BEOL structure.

4. The semiconductor structure of claim 2, wherein the frontside contact structures comprise a first frontside gate contact structure electrically connecting a gate structure of the non-stacked transistor to the frontside BEOL structure, a second gate contact structure electrically connecting a gate structure of each of the transistors of the stacked transistor to the frontside BEOL structure, a first frontside source/drain contact structure electrically connecting a first source/drain region of the non-stacked transistor to the frontside BEOL structure, and a second frontside source/drain contact structure electrically connecting a first source/drain region and a second source/drain region of a first transistor of the two or more transistors of the stacked transistor to the frontside BEOL structure.

5. The semiconductor structure of claim 4, wherein the backside interconnect comprises a first backside metal level comprising a plurality of first backside electrically conductive structures, and a second backside metal level located on the first backside metal level and comprising a plurality of second backside electrically conductive structures.

6. The semiconductor structure of claim 5, wherein one of the first backside electrically conductive structures of the plurality of first backside electrically conductive structures is electrically connected to a second source/drain region of the non-stacked transistor by a first backside source/drain contact structure, and at least two other first backside electrically conductive structures of the plurality of first backside electrically conductive structures are electrically connected to a first source/drain region and a second source/drain region of a second transistor of the two or more transistors of the stacked transistor by second backside source/drain contact structures.

7. The semiconductor structure of claim 6, wherein one of the second backside electrically conductive structures is electrically connected to the first backside electrically conductive structure that is electrically connected to the second source/drain region of the non-stacked transistor by a first backside metal via.

8. The semiconductor structure of claim 6, wherein another of the second backside electrically conductive structures is electrically connected to the first backside electrically conductive structures that is electrically connected to the second source/drain region of one of the transistors of the stacked transistor by a second backside metal via.

9. The semiconductor structure of claim 1, wherein the non-stacked transistor is a nanosheet transistor.

10. The semiconductor structure of claim 9, wherein the two or more transistors of the stacked transistor are nanosheet transistors.

11. The semiconductor structure of claim 10, further comprising:
a dielectric structure separating each nanosheet transistor.

12. The semiconductor structure of claim 11, wherein the dielectric structure is continuous and comprises a dielectric gate cut pillar, a middle dielectric isolation layer, a stacked device gate spacer, and a bottom dielectric isolation layer, wherein a first end of the middle dielectric isolation layer is connected to the dielectric gate cut pillar, and a second end of the middle dielectric isolation layer is connected to the bottom dielectric isolation layer by the stacked device gate spacer, and the dielectric gate cut pillar contacts the frontside interconnect and the bottom dielectric isolation layer contacts the backside interconnect.

13. The semiconductor structure of claim 12, wherein the middle dielectric isolation layer and the bottom dielectric isolation layer are orientated parallel to each semiconductor material nanosheet of each nanosheet transistor of the two or more transistors of the stacked transistor, and the dielectric gate cut pillar and the stacked device gate spacer are orientated perpendicular to each semiconductor material nanosheet of each nanosheet transistor of the two or more transistors of the stacked transistor.

14. The semiconductor structure of claim 1, wherein each of the two or more transistors of the stacked transistor is of a same conductivity type.

15. The semiconductor structure of claim 1, wherein the two or more transistors of the stacked transistor comprise a top transistor having a first conductivity type and a bottom transistor having a second conductivity type that is different from the first conductivity type.

16. The semiconductor structure of claim 15, wherein the first conductivity type is n-type, and the second conductivity type is p-type.

17. The semiconductor structure of claim 15, wherein the first conductivity type is p-type, and the second conductivity type is n-type.

18. The semiconductor structure of claim 1, wherein the non-stacked transistor and the stacked transistor have a same device height, and the non-stacked transistor has an upper surface and a lower surface, wherein the upper surface of the non-stacked transistor is coplanar with an upper surface of the stacked transistor, and the lower surface of the non-stacked transistor is coplanar with a lower surface of the stacked transistor.

19. The semiconductor structure of claim 1, wherein non-stacked transistor includes a vertically stacked semiconductor nanosheets, and each of the transistors of the stacked transistor includes a vertically stacked semiconductor nanosheets, wherein a total number of vertically stacked semiconductor nanosheets of the non-stacked transistor is equal to, or greater than, a total number of vertically stacked semiconductor nanosheets of the two or more transistors of the stacked transistor.

20. The semiconductor structure of claim 1, wherein the non-stacked transistor is a logic device, and the two or more transistors of the stacked transistor are static access memory (SRAM) devices.
